(19) United States
(12) Patent Application Publication
(10) Pub. No.: US 2025/0391798 A1
(43) Pub. Date: Dec. 25, 2025

(54) SEMICONDUCTOR PACKAGE

(71) Applicant: SAMSUNG ELECTRONICS CO., LTD., Suwon-si (KR)

(72) Inventor: HYUNSOO CHUNG, Suwon-si (KR)

(73) Assignee: SAMSUNG ELECTRONICS CO., LTD., Suwon-si (KR)

(21) Appl. No.: 18/986,118

(22) Filed: Jan. 14, 2025

(30) Foreign Application Priority Data
Jun. 25, 2024 (KR) 10-2024-0082800

(51) Int. Cl. H01L 23/00; H01L 23/48; H01L 23/498; H01L 25/16; H10B 80/00

(52) U.S. Cl. CPC H01L 24/24; H01L 23/481; H01L 25/162; H01L 23/49822; H01L 24/08; H01L 24/32; H01L 2224/08146; H01L 2224/08225; H01L 2224/24137; H01L 2224/24146; H01L 2224/32145; H01L 2224/32225; H10B 80/00

(57) ABSTRACT

A semiconductor package includes: a lower substrate; a first semiconductor chip on the lower substrate; a second semiconductor chip on the lower substrate and spaced apart from the first semiconductor chip in a first direction, the first direction being parallel to a top surface of the lower substrate; a lower dielectric layer on the lower substrate, the first semiconductor chip, and the second semiconductor chip; an upper redistribution substrate on the lower dielectric layer; a third semiconductor chip on the upper redistribution substrate; a base chip on the upper redistribution substrate and spaced apart from the third semiconductor chip in the first direction; and at least one memory chip stacked in a vertical direction on the base chip, the vertical direction being perpendicular to the top surface of the lower substrate, and wherein the lower dielectric layer includes an inorganic dielectric material.

### CROSS-REFERENCE TO RELATED APPLICATION

This U.S. non-provisional application claims priority under 35 U.S.C § 119 to Korean Patent Application No. 10-2024-0082800, filed on Jun. 25, 2024, in the Korean Intellectual Property Office, the disclosure of which is hereby incorporated by reference in its entirety.

### BACKGROUND

### 1. Field

Embodiments of the present disclosure relate to a semiconductor package and a method of fabricating the same, and more particularly, to a stacked semiconductor package in which a plurality of semiconductor chips are stacked on a substrate and a method of fabricating the same.

### 2. Brief Description of Background Art

In response to the rapid development of the electronic industry and user demands, electronic products have become smaller and increasingly multifunctional. There are also increased needs for miniaturization and multi-functionality of semiconductor devices used for electronic products. Accordingly, there has been proposed a semiconductor package in which a plurality of semiconductor chips having through electrodes are stacked in a vertical direction.

### SUMMARY

Some embodiments of the present disclosure provide a semiconductor package having improved extensibility and reliability.

According to some embodiments of the present disclosure, a semiconductor package may be provided and include: a lower substrate; a first semiconductor chip on the lower substrate; a second semiconductor chip on the lower substrate and spaced apart from the first semiconductor chip in a first direction, the first direction being parallel to a top surface of the lower substrate; a lower dielectric layer on the lower substrate, the first semiconductor chip, and the second semiconductor chip; an upper redistribution substrate on the lower dielectric layer; a third semiconductor chip on the upper redistribution substrate; a base chip on the upper redistribution substrate and spaced apart from the third semiconductor chip in the first direction; and at least one memory chip stacked in a vertical direction on the base chip, the vertical direction being perpendicular to the top surface of the lower substrate, and wherein the lower dielectric layer includes an inorganic dielectric material.

According to some embodiments of the present disclosure, a semiconductor package may be provided and include: a first semiconductor chip; a second semiconductor chip spaced apart from the first semiconductor chip in a first direction; a lower dielectric layer on the first semiconductor chip and the second semiconductor chip; an upper redistribution substrate on the lower dielectric layer; a third semiconductor chip on the upper redistribution substrate; a base chip on the upper redistribution substrate and spaced apart from the third semiconductor chip in the first direction; at least one memory chip stacked in a second direction on the base chip, the second direction being perpendicular to the first direction; and an upper dielectric layer on the upper redistribution substrate, and on a side surface of the third semiconductor chip, the base chip, and the at least one memory chip, wherein the upper dielectric layer includes a material different from a material of the lower dielectric layer.

According to some embodiments of the present disclosure, a semiconductor package may be provided and include: a package substrate; a lower substrate on the package substrate; a first semiconductor chip on the lower substrate; a second semiconductor chip spaced from the first semiconductor chip apart in a first direction, the first direction being parallel to a top surface of the package substrate; an upper redistribution substrate on the first semiconductor chip and the second semiconductor chip; a third semiconductor chip on the upper redistribution substrate; a base chip on the upper redistribution substrate and spaced apart from the third semiconductor chip in the first direction; and at least one memory chip stacked in a second direction on the base chip, the second direction being perpendicular to the top surface of the package substrate, wherein an uppermost surface of the first semiconductor chip is at a same level as a level of an uppermost surface of the second semiconductor chip, and wherein a lowermost surface of the third semiconductor chip is at a same level as a level of a lowermost surface of the base chip.

### BRIEF DESCRIPTION OF DRAWINGS

FIG. 1 illustrates a plan view showing a semiconductor package according to some embodiments of the present disclosure.

FIG. 2 illustrates a cross-sectional view taken along a line A-A′ of FIG. 1.

FIG. 3 illustrates an enlarged view showing a section M of FIG. 2.

FIG. 4 illustrates an enlarged view showing a section N of FIG. 2.

FIG. 5 illustrates an enlarged view showing a base chip and a plurality of memory chips depicted in FIG. 2.

FIGS. 6, 7, 8, 9, 10, and 11 illustrate cross-sectional views taken along the line A-A′ of FIG. 1, showing a method of fabricating a semiconductor package according to some embodiments of the present disclosure.

FIG. 12 illustrates a cross-sectional view taken along the line A-A′ of FIG. 1, showing a semiconductor package according to some embodiments of the present disclosure.

### DETAILED DESCRIPTION

The following will now describe in detail some non-limiting example embodiments of the present disclosure with reference to the accompanying drawings.

It will be understood that when an element or layer is referred to as being “on,” “connected to,” or “coupled to” another element or layer, it can be directly on, connected to, or coupled to the other element or layer or intervening elements or layers may be present. In contrast, when an element or layer is referred to as being “directly on,” “directly connected to,” or “directly coupled to” another element or layer, there are no intervening elements or layers present.

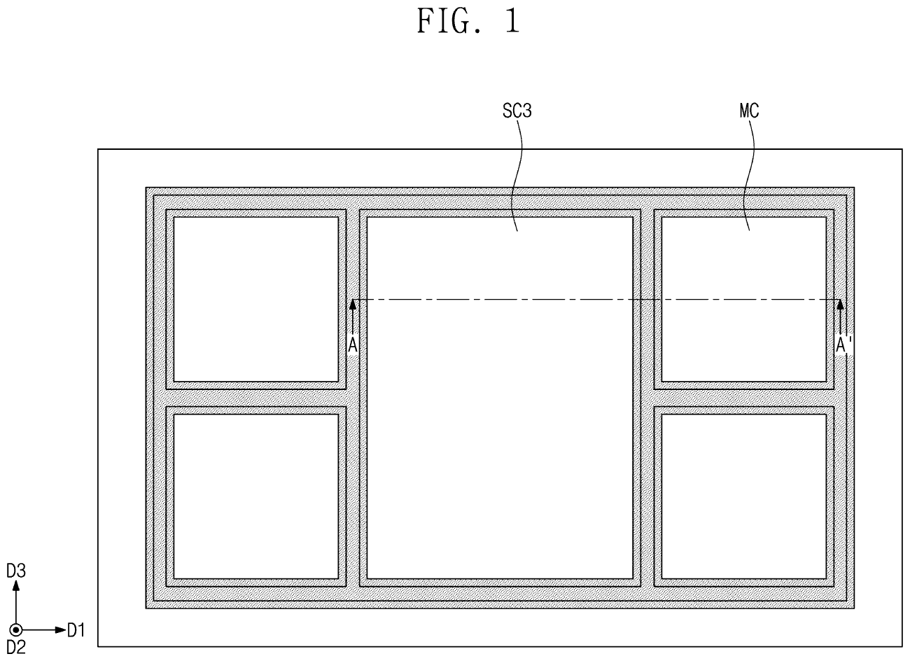

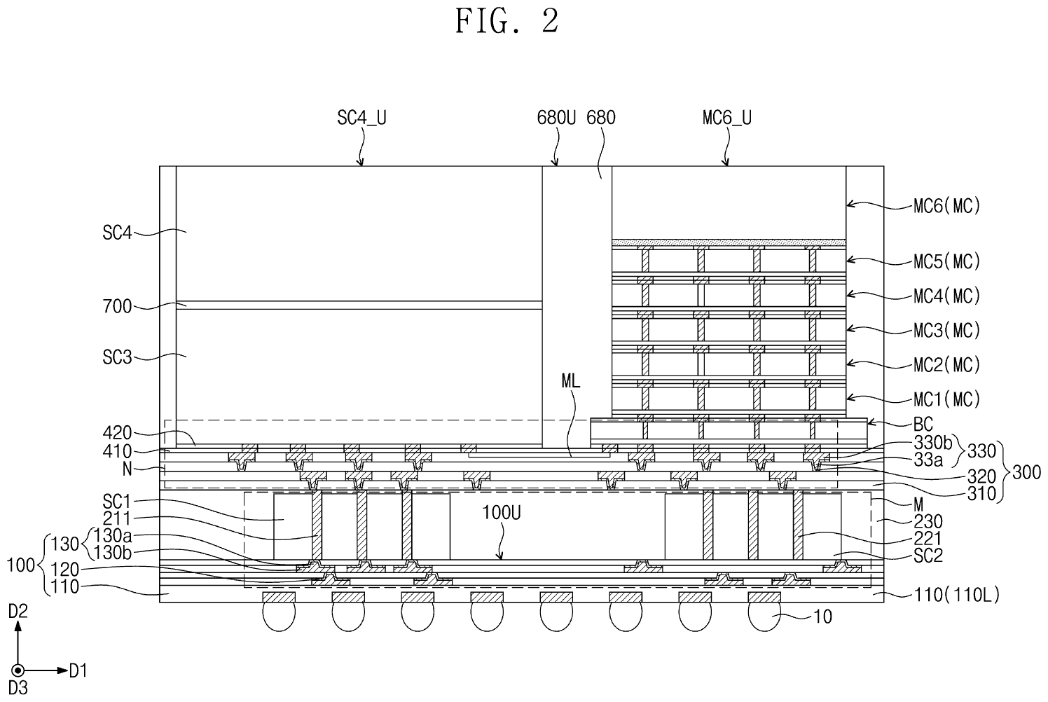

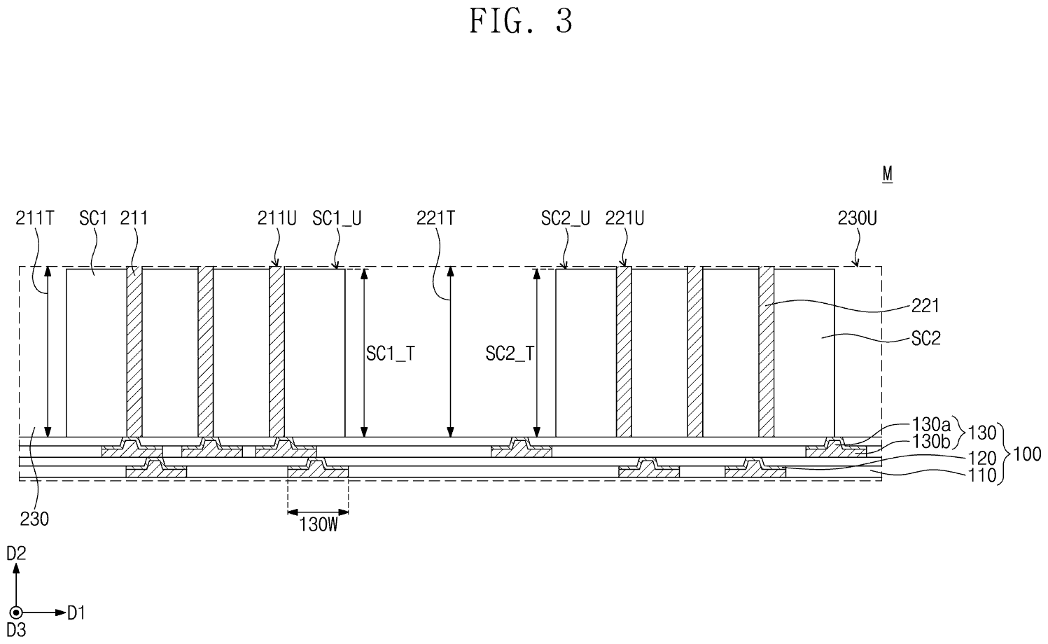

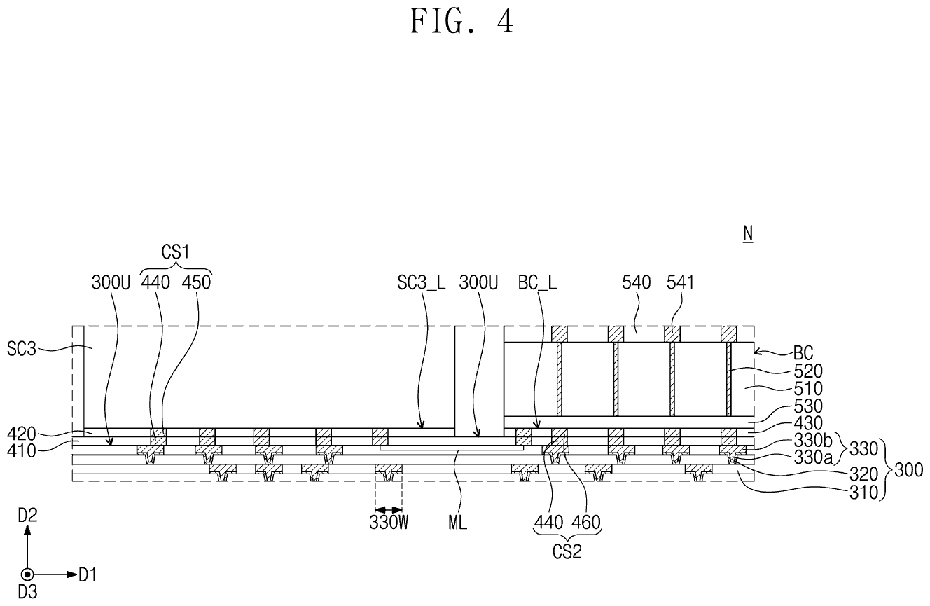

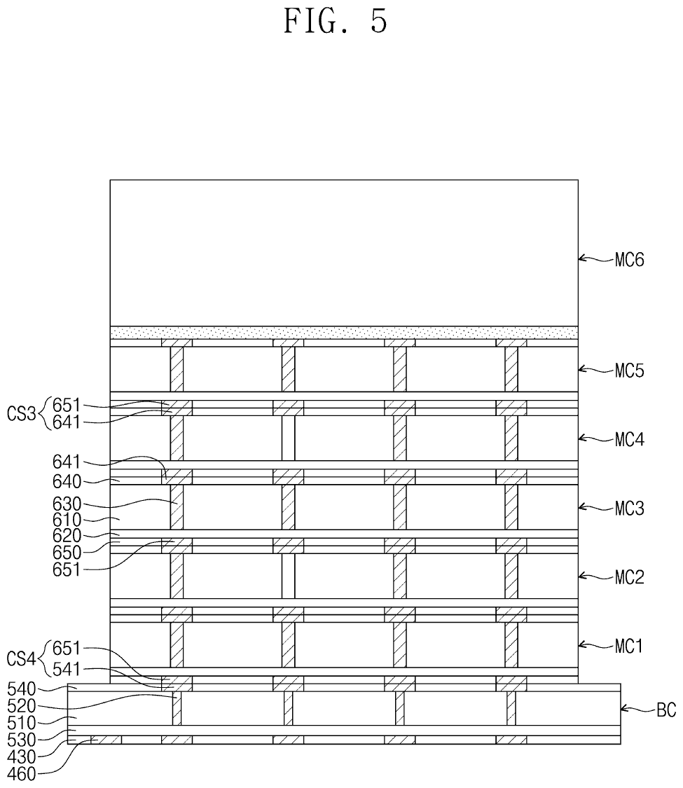

FIG. 1 illustrates a plan view showing a semiconductor package according to some embodiments of the present disclosure. FIG. 2 illustrates a cross-sectional view taken along line A-A′ of FIG. 1. FIG. 3 illustrates an enlarged view showing section M of FIG. 2. FIG. 4 illustrates an enlarged view showing section N of FIG. 2. FIG. 5 illustrates an enlarged view showing a base chip and a plurality of memory chips depicted in FIG. 2.

Referring to FIGS. 1 to 5, a lower substrate 100 may be provided. The lower substrate 100 may be a lower redistribution substrate. For example, the lower substrate 100 may include a lower redistribution seed pattern 120, a lower redistribution pattern 130 on the lower redistribution seed pattern 120, and lower redistribution dielectric layers 110 that cover the lower redistribution pattern 130. The lower redistribution pattern 130 may be provided in plural. The lower redistribution pattern 130 may include a lower redistribution contact 130a and a lower redistribution line 130b connected to the lower redistribution contact 130a.

The lower redistribution contact 130a may penetrate a corresponding one of the lower redistribution dielectric layers 110, and the lower redistribution line 130b may be disposed on the corresponding one of the lower redistribution dielectric layers 110 to come into connection with the lower redistribution contact 130a. The lower redistribution seed pattern 120 may be interposed between the lower redistribution contact 130a and the corresponding one of the lower redistribution dielectric layers 110, and may extend between the lower redistribution line 130b and the corresponding one of the lower redistribution dielectric layers 110.

The lower redistribution pattern 130 may include a metallic material, such as one or more from among copper, titanium, and an alloy thereof. The lower redistribution seed pattern 120 may include a metallic material, such as one or more from among copper, titanium, and an alloy thereof. Each of the lower redistribution dielectric layers 110 may include an organic dielectric material, such as one or more from among epoxy resin and photosensitive polymer.

In this disclosure, a first direction D1 may be defined to refer to a direction parallel to a top surface 100U of the lower substrate 100. A second direction D2 may be defined to refer to a direction perpendicular to the top surface 100U of the lower substrate 100. A third direction D3 may be defined to refer to a direction that is parallel to the top surface 100U of the lower substrate 100 and crosses (e.g., is parallel to) the first direction D1.

First connection terminals 10 may be disposed beneath the lower substrate 100. The first connection terminals 10 may be disposed beneath a lowermost one of the lower redistribution dielectric layers 110. The first connection terminals 10 may include solder balls or solder bumps. Based on type and placement of the first connection terminals 10, the first connection terminals 10 may be provided in the form of a ball grid array (BGA) type, a fine ball-grid array (FBGA) type, or a land grid array (LGA) type. The first connection terminals 10 may be an alloy that includes at least one selected from among tin (Sn), silver (Ag), copper (Cu), nickel (Ni), bismuth (Bi), indium (In), antimony (Sb), and cerium (Ce).

A first semiconductor chip SC1 may be disposed on the lower substrate 100. The first semiconductor chip SC1 may include a first via 211 that penetrates the first semiconductor chip SC1. The first via 211 may include a metallic material, such as one or more from among copper, titanium, and an alloy thereof. The first via 211 may be connected (e.g., electrically connected) to the lower substrate 100. The first via 211 may be electrically connected to the lower redistribution pattern 130 of the lower substrate 100. The first semiconductor chip SC1 may be a memory chip such as, for example, a volatile memory device such as a static random access memory (SRAM) or nonvolatile memory device such as a Flash memory, a phase change random access memory (FRAM), a magneto-resistive random access memory (MRAM), ferroelectric random access memory (FeRAM), or resistive random access memory (RRAM).

A second semiconductor chip SC2 may be disposed on the lower substrate 100, and may be spaced apart in the first direction D1 from the first semiconductor chip SC1. The second semiconductor chip SC2 may include a second via 221 that penetrates the second semiconductor chip SC2. The second via 221 may include a metallic material, such as one or more from among copper, titanium, and an alloy thereof. The second semiconductor chip SC2 may be, for example, a dummy semiconductor chip, and may not be connected (e.g., electrically connected) to the lower substrate 100. For example, the second via 221 may not be electrically connected to the lower redistribution pattern 130 of the lower substrate 100. According to an embodiment, the second semiconductor chip SC2 may be a memory chip, and in this case, different from that shown, the second semiconductor chip SC2 may be connected (e.g., electrically connected) to the lower substrate 100, and the second via 221 may be electrically connected to the lower redistribution pattern 130 of the lower substrate 100.

An uppermost surface SC1_U of the first semiconductor chip SC1 and an uppermost surface SC2_U of the second semiconductor chip SC2 may be located at the same level from the top surface 100U of the lower substrate 100. The uppermost surface SC1_U of the first semiconductor chip SC1 and the uppermost surface SC2_U of the second semiconductor chip SC2 may be positioned on the same plane. A thickness SC1_T in the second direction D2 of the first semiconductor chip SC1 may be the same as a thickness SC2_T in the second direction D2 of the second semiconductor chip SC2.

An uppermost surface 211U of the first via 211 that penetrates the first semiconductor chip SC1 may be located at the same level as a level of an uppermost surface 221U of the second via 221 that penetrates the second semiconductor chip SC2. The uppermost surface 211U of the first via 211 and the uppermost surface 221U of the second via 221 may be positioned on the same plane. A thickness 211T in the second direction D2 of the first via 211 may be the same as a thickness 221T in the second direction D2 of the second via 221.

A lower dielectric layer 230 may be disposed on the lower substrate 100, and may cover the first semiconductor chip SC1 and the second semiconductor chip SC2. An uppermost surface 230U of the lower dielectric layer 230 may be positioned on the same plane on which are positioned the uppermost surface 221U of the first via 211 and the uppermost surface 221U of the second via 221. The lower dielectric layer 230 may include a material different from a material of the lower redistribution dielectric layers 110. The lower dielectric layer 230 may include an inorganic dielectric material, such as one or more from among silicon oxide, silicon nitride, and silicon oxynitride.

An upper redistribution substrate 300 may be disposed on the lower dielectric layer 230. The upper redistribution substrate 300 may include an upper redistribution seed pattern 320, an upper redistribution pattern 330 on the upper redistribution seed pattern 320, upper redistribution dielectric layers 310 that cover the upper redistribution pattern 330, and a metal line ML.

The upper redistribution pattern 330 may be provided in plural. The number of the upper redistribution patterns 330 may be greater than a number of the lower redistribution patterns 130. A ration of the number of the upper redistribution patterns 330 and the number of the lower redistribution patterns 130 may range from, for example, about 10:1 to about 5:1. The upper redistribution pattern 330 may include an upper redistribution line 330b and an upper redistribution contact 330a connected to the upper redistribution line 330b.

The upper redistribution contact 330a may penetrate a corresponding one of the upper redistribution dielectric layers 310, and the upper redistribution line 330b may be disposed on the corresponding one of the upper redistribution dielectric layers 310 to come into connection with the upper redistribution contact 330a. The upper redistribution seed pattern 320 may be interposed between the upper redistribution contact 330a and the corresponding one of the upper redistribution dielectric layers 310, and may extend between the upper redistribution line 330b and the corresponding one of the upper redistribution dielectric layers 310.

The upper redistribution pattern 330 may include a metallic material, such as one or more from among copper, titanium, and an alloy thereof. The upper redistribution seed pattern 320 may include a metallic material, such as one or more from among copper, titanium, and an alloy thereof.

Each of the upper redistribution dielectric layers 310 may include a material different from a material of the lower redistribution dielectric layers 110 and identical to a material of the lower dielectric layer 230. Each of the upper redistribution dielectric layers 310 may include an inorganic dielectric material, such as one or more from among silicon oxide, silicon nitride, and silicon oxynitride.

Referring to FIGS. 3 and 4, a width 330W in the first direction D1 of the upper redistribution pattern 330 may be less than a width 130W in the first direction D1 of the lower redistribution pattern 130. A range of from about 1:10 to about 1:5 may be a ratio of the width 330W in the first direction D1 of the upper redistribution pattern 330 to the width 130W in the first direction D1 of the lower redistribution pattern 130. For example, the width 330W in the first direction D1 of the upper redistribution pattern 330 may range from about 0.1 nm to about 5 nm, and the width 130W in the first direction D1 of the lower redistribution pattern 130 may range from about 10 nm to about 20 nm.

The width 330W in the first direction D1 of the upper redistribution pattern 330 may refer to a maximum width in the first direction D1 of the upper redistribution pattern 330. The width 130W in the first direction D1 of the lower redistribution pattern 130 may refer to a maximum width in the first direction D1 of the lower redistribution pattern 130.

According to some embodiments of the present disclosure, the first semiconductor chip SC1 may be a memory chip, and the upper redistribution substrate 300 may be disposed on the first semiconductor chip SC1. Therefore, the first semiconductor chip SC1 may have an improved thermal management system and may be prevented from heat-induced degradation of performance. Accordingly, a semiconductor package may be provided with increased reliability.

In addition, the lower dielectric layer 230 and the upper redistribution dielectric layer 310 may include the same material as each other. Thus, as an increased adhesive force is provided between the lower dielectric layer 230 and the upper redistribution dielectric layer 310, a semiconductor package may have increased reliability.

Referring back to FIGS. 1 to 5, a third semiconductor chip SC3 may be disposed on the upper redistribution substrate 300. The third semiconductor chip SC3 may include a graphic processing unit (GPU) die, a central processing unit (CPU) die, or a system-on-chip (SoC). For example, the third semiconductor chip SC3 may be a logic chip.

A base chip BC may be disposed on the upper redistribution substrate 300, and may be spaced apart in the first direction D1 from the third semiconductor chip SC3. The base chip BC may include a first semiconductor substrate 510, a first interlayer dielectric layer 530 disposed beneath the first semiconductor substrate 510, and a third via 520 that penetrates the base chip BC (e.g., the first semiconductor substrate 510). A lowermost surface SC3_L of the third semiconductor chip SC3 and a lowermost surface BC_L of the base chip BC may be located at the same level as each other. The third semiconductor chip SC3 and the base chip BC may be connected through the upper redistribution substrate 300.

A first adhesive layer 410 may be disposed on an uppermost surface 300U of the upper redistribution substrate 300. The first adhesive layer 410 may be disposed beneath the third semiconductor chip SC3 and the base chip BC. The first adhesive layer 410 may be interposed between the upper redistribution substrate 300 and the third semiconductor chip SC3, and may extend between the upper redistribution substrate 300 and the base chip BC. A second adhesive layer 420 may be disposed beneath the lowermost surface SC3_L of the third semiconductor chip SC3. The second adhesive layer 420 may be interposed between the third semiconductor chip SC3 and the first adhesive layer 410. The first adhesive layer 410 and the second adhesive layer 420 may be in direct contact with each other, and may include the same material as each other. A third adhesive layer 430 may be disposed beneath the lowermost surface BC_L of the base chip BC. The third adhesive layer 430 may be interposed between the base chip BC and the first adhesive layer 410. The first adhesive layer 410 and the third adhesive layer 430 may be in direct contact with each other, and may include the same material as each other.

A first connection structure CS1 may be disposed penetrating the first adhesive layer 410 and the second adhesive layer 420. The third semiconductor chip SC3 and the upper redistribution substrate 300 may be connected (e.g., electrically connected) to each other through the first connection structure CS1. The first connection structure CS1 may include a first connection part 440 disposed in the first adhesive layer 410 and a second connection part 450 disposed in the second adhesive layer 420. The first connection part 440 and the second connection part 450 may be in direct contact with each other, and may include the same metal as each other. The first connection part 440 and the second connection part 450 may include, for example, copper. The upper redistribution substrate 300 and the third semiconductor chip SC3 may be directly bonded or hybrid copper bonded to each other through the first connection structure CS1.

A second connection structure CS2 may be disposed penetrating the first adhesive layer 410 and the third adhesive layer 430. The base chip BC and the upper redistribution substrate 300 may be connected (e.g., electrically connected) to each other through the second connection structure CS2. The second connection structure CS2 may include a first connection part 440 disposed in the first adhesive layer 410 and a third connection part 460 disposed in the third adhesive layer 430. The first connection part 440 and the third connection part 460 may be in direct contact with each other, and may include the same metal as each other. The first connection part 440 and the third connection part 460 may include, for example, copper. The upper redistribution substrate 300 and the base chip BC may be directly bonded or hybrid copper bonded to each other through the second connection structure CS2.

According to some embodiments of the present disclosure, as the third semiconductor chip SC3 and the base chip BC are connected (e.g., electrically connected) through the upper redistribution substrate 300, a separate connection chip may not be needed to provide a semiconductor package whose required cost is reduced.

In addition, the lowermost surface SC3_L of the third semiconductor chip SC3 and the lowermost surface BC_L of the base chip BC may be located at the same level as each other. The third semiconductor chip SC3 and the base chip BC may be connected with a shortest route. Thus, a semiconductor package may be provided with a reduced data transfer path.

Moreover, as each of the upper redistribution dielectric layers 310 includes an inorganic dielectric material, it may be possible to achieve a fine patterning of the upper redistribution patterns 330. This may lead to a relative reduction in the width 330W in the first direction D1 of the upper redistribution patterns 330 and an easy increase in the integration of the upper redistribution patterns 330 in the upper redistribution substrate 300. The increase in the integration of the upper redistribution patterns 330 may improve connectivity between the third semiconductor chip SC3 and the base chip BC.

A plurality of memory chips MC may be stacked in the second direction D2 on the base chip BC. The plurality of memory chips MC may be the same type of semiconductor chip as each other, and may include memory circuits for data storage. The plurality of memory chips MC may be dynamic random-access memory (DRAM) chips or NAND Flash chips. The base chip BC may include a logic circuit for driving the plurality of memory chips MC, and may not include memory circuits for data storage.

Referring to FIG. 5, a first memory chip MC1, a second memory chip MC2, a third memory chip MC3, a fourth memory chip MC4, a fifth memory chip MC5, and a sixth memory chip MC6 may be stacked on the base chip BC, but embodiments of the present disclosure are not limited thereto and the number of the plurality of memory chips MC may be less or greater than six. According to some embodiments of the present disclosure, the plurality of memory chips MC may constitute a high bandwidth memory (HBM) structure.

The base chip BC may include a serial-parallel conversion circuit, a design for test (DFT), a joint test action group (JTAG), a test logic circuit such as a memory built-in self-test (MBIST), or a signal interface circuit such as PHY. The base chip BC may be, for example, a logic chip for controlling the plurality of memory chips MC.

Each of the plurality of memory chips MC may include a second semiconductor substrate 610 and a second interlayer dielectric layer 620 disposed beneath the second semiconductor substrate 610. A third connection structure CS3 may be interposed between the plurality of memory chips MC.

The second semiconductor substrate 610 may be one or more of a semiconductor substrate formed of a semiconductor such as silicon, a silicon-on-insulator (SOI) substrate, and a dielectric substrate. Each of the plurality of memory chips MC may have a fourth via 630 that penetrate therethrough (e.g., through the second semiconductor substrate 610). The fourth via 630 may be provided in plural. The fourth via 630 may include metal, such as copper, aluminum, or tungsten. An uppermost one (e.g., the sixth memory chip MC6) among the plurality of memory chips MC may not include the fourth via 630.

An upper adhesive layer 640 may be disposed on the second semiconductor substrate 610, and an upper connection part 641 may be disposed in the upper adhesive layer 640. A lower adhesive layer 650 may be disposed beneath the second interlayer dielectric layer 620, and a lower connection part 651 may be disposed in the lower adhesive layer 650. The upper adhesive layer 640 and the lower adhesive layer 650 may include the same material as each other, and may have a mono-layered or multi-layered structure of at least one selected from, for example, silicon oxide, silicon nitride, and silicon carbonitride. The upper connection part 641 and the lower connection part 651 may include the same material as each other, such as a metallic material. The upper connection part 641 and the lower connection part 651 may include, for example, copper.

The upper adhesive layer 640 may be in direct contact with the lower adhesive layer 650 adjacent thereto, and the upper connection part 641 may be in direct contact with the lower connection part 651 adjacent thereto. The upper connection part 641 and the lower connection part 651 may be in direct contact with each other to constitute the third connection structure CS3.

Each of the plurality of memory chips MC and its adjacent memory chip may be directly bonded or hybrid copper bonded to each other through the third connection structure CS3. For example, the upper adhesive layer 640 of the second memory chip MC2 may be in direct contact with the lower adhesive layer 650 of the third memory chip MC3. The upper connection part 641 of the second memory chip MC2 may be in direct contact with the lower connection part 651 of the third memory chip MC3, thereby constituting the third connection structure CS3.

A fourth adhesive layer 540 may be disposed on the first semiconductor substrate 510 of the base chip BC, and a fourth connection part 541 may be disposed in the fourth adhesive layer 540. The fourth adhesive layer 540 on the base chip BC may be in direct contact with the lower adhesive layer 650 of a lowermost one (e.g., the first memory chip MC1) among the plurality of memory chips MC. The fourth connection part 541 may be in direct contact with the lower connection part 651 of the lowermost memory chip (e.g., the first memory chip MC1), thereby constituting the fourth connection structure CS4. The base chip BC and the lowermost memory chip (e.g., the first memory chip MC1) may be directly bonded or hybrid copper bonded to each other through the fourth connection structure CS4.

A fourth semiconductor chip SC4 may be disposed on the third semiconductor chip SC3. A die adhesive layer 700 may be disposed on a bottom surface of the fourth semiconductor chip SC4. The die adhesive layer 700 may be interposed between the third semiconductor chip SC3 and the fourth semiconductor chip SC4. The fourth semiconductor chip SC4 may be adhered to the third semiconductor chip SC3 through the die adhesive layer 700.

An uppermost surface SC4_U of the fourth semiconductor chip SC4 may be located at the same level as a level of an uppermost surface MC6_U of an uppermost one (e.g., the sixth memory chip MC6) among the plurality of memory chips MC. The fourth semiconductor chip SC4 may not be electrically connected to the third semiconductor chip SC3 and, for example, may be a dummy semiconductor chip.

An upper dielectric layer 680 may cover the third semiconductor chip SC3, the fourth semiconductor chip SC4, the base chip BC, and the plurality of memory chips MC. An uppermost surface 680U of the upper dielectric layer 680 may be located at the same level as the level of the uppermost surface SC4_U of the fourth semiconductor chip SC4 and the level of the uppermost surface MC6_U of the uppermost memory chip (e.g., the sixth memory chip MC6) among the plurality of memory chips MC.

The upper dielectric layer 680 may include a material different from a material of the lower dielectric layer 230. The upper dielectric layer 680 may include a material the same as a material of the lower redistribution dielectric layers 110. The upper dielectric layer 680 may include an organic dielectric material, such as an epoxy molding compound.

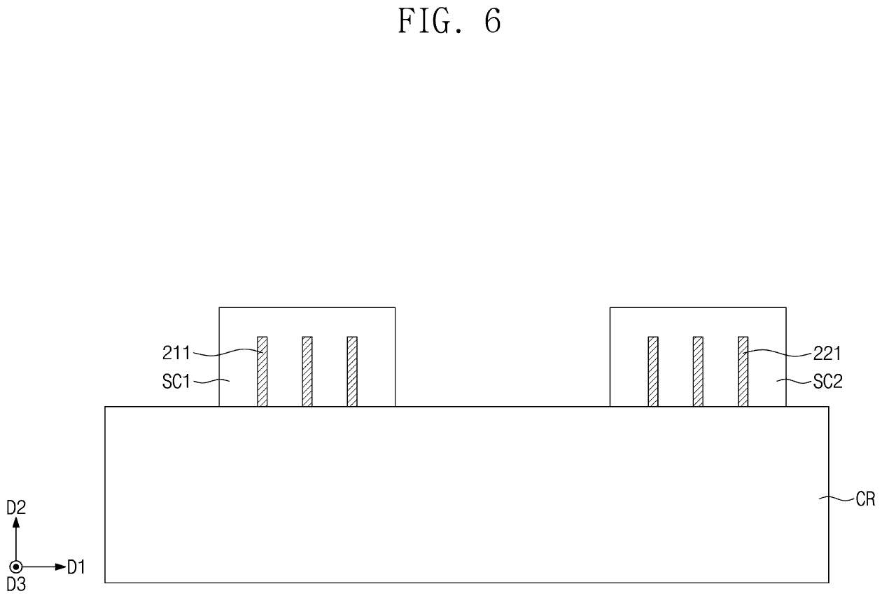

FIGS. 6, 7, 8, 9, 10, and 11 illustrate cross-sectional views taken along a line A-A′ of FIG. 1, showing a method of fabricating a semiconductor package according to some embodiments of the present disclosure. For brevity of description, omission may be made to avoid a repetitive explanation of the semiconductor package discussed with reference to FIGS. 1 to 5.

Referring to FIG. 6, a first semiconductor chip SC1 and a second semiconductor chip SC2 may be provided on a carrier substrate CR. The first semiconductor chip SC1 may include a first via 211 that penetrates the first semiconductor chip SC1. The second semiconductor chip SC2 may include a second via 221 that penetrates the second semiconductor chip SC2.

Each of the first via 211 and the second via 221 may have a top surface and a bottom surface that are opposite to each other in the second direction D2. The bottom surface of the first via 211 may be substantially coplanar with the bottom surface of the first semiconductor chip SC1, and the first semiconductor chip SC1 may cover the top surface of the first via 211. The bottom surface of the second via 221 may be substantially coplanar with the bottom surface of the second semiconductor chip SC2, and the second semiconductor chip SC2 may cover the top surface of the second via 221.

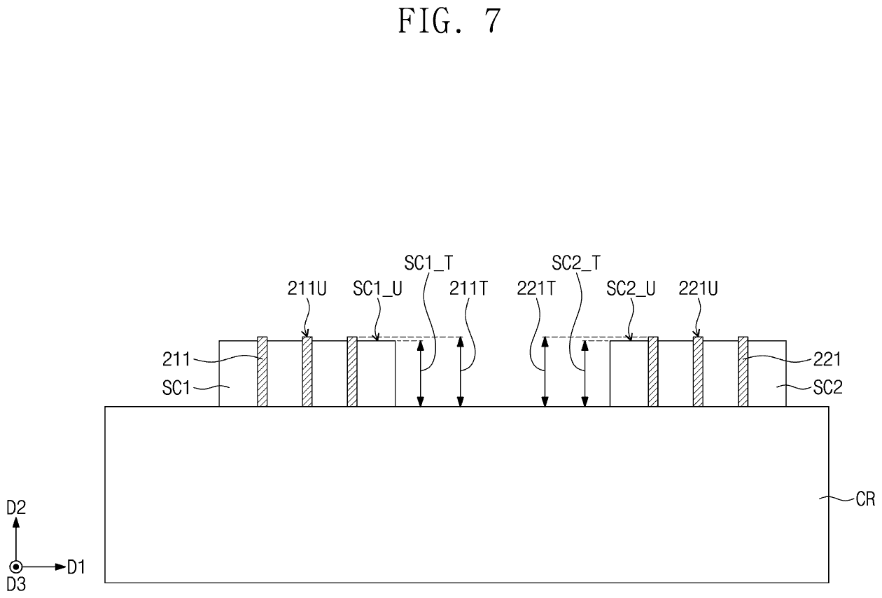

Referring to FIG. 7, an uppermost surface 211U of the first via 211 may be exposed by the first semiconductor chip SC1. The first semiconductor chip SC1 may undergo a backside thinning process to expose the uppermost surface 211U of the first via 211. An uppermost surface 221U of the second via 221 may be exposed by the second semiconductor chip SC2. The second semiconductor chip SC2 may undergo the backside thinning process to expose the uppermost surface 221U of the second semiconductor chip SC2. The backside thinning process may simultaneously expose the uppermost surface 211U of the first via 211 and the uppermost surface 221U of the second via 221.

The uppermost surface 211U of the first via 211 and the uppermost surface 221U of the second via 221 may be located at the same level as each other and positioned on the same plane as each other. An uppermost surface SC1_U of the first semiconductor chip SC1 and an uppermost surface SC2_U of the second semiconductor chip SC2 may be located at the same level as each other and positioned on the same plane as each other.

A thickness SC1_T I in the second direction D2 of the first semiconductor chip SC1 may be the same as a thickness SC2_T in the second direction D2 of the second semiconductor chip SC2. The uppermost surface 211U of the first via 211 that penetrates the first semiconductor chip SC1 may be located at the same level as the level of the uppermost surface 221U of the second via 221 that penetrates the second semiconductor chip SC2.

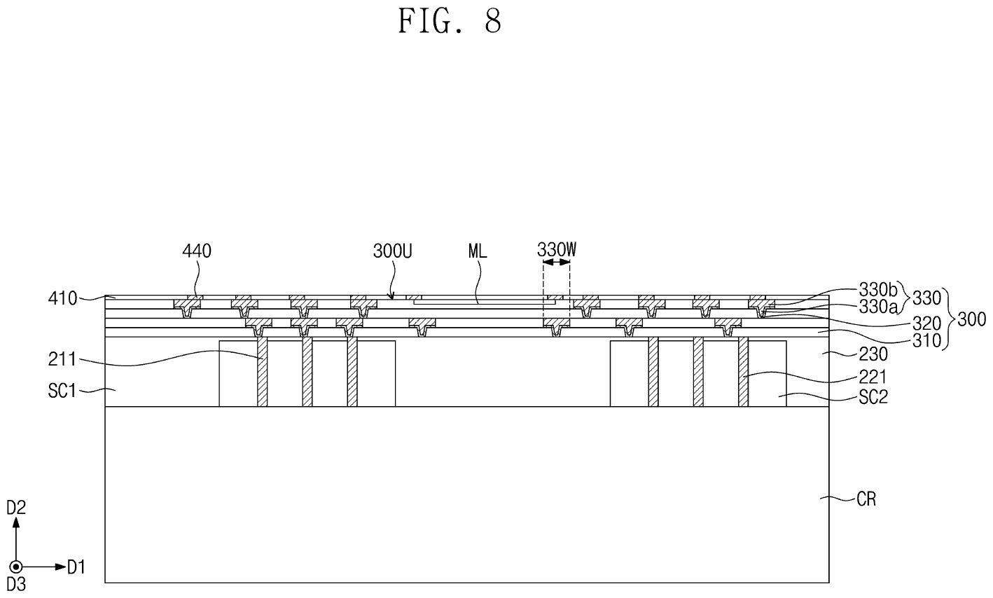

Referring to FIG. 8, a lower dielectric layer 230 may cover the first semiconductor chip SC1 and the second semiconductor chip SC2. The lower dielectric layer 230 may cover exposed end portions of the first via 211 and the second via 221. The formation of the lower dielectric layer 230 may include, for example, depositing an inorganic dielectric material on the carrier substrate CR, and planarizing the inorganic dielectric material until the uppermost surface 211U of the first via 211 and the uppermost surface 221U of the second via 221 are exposed.

An upper redistribution substrate 300 may be formed on the lower dielectric layer 230. The formation of the upper redistribution substrate 300 may include, for example, forming upper redistribution dielectric layers 310 on the lower dielectric layer 230, forming upper redistribution contact holes that penetrate the upper redistribution dielectric layers 310, forming upper redistribution seed patterns 320 that partially fill the upper redistribution contact holes and extend onto top surfaces of the upper redistribution dielectric layers 310, and performing an electroplating process in which the upper redistribution seed patterns 320 are used to form upper redistribution contacts 330a and upper redistribution lines 330b. The upper redistribution contacts 330a may fill unoccupied portions of the upper redistribution contact holes, and the upper redistribution lines 330b may extend onto the upper redistribution dielectric layers 310. The upper redistribution contacts 330a and the upper redistribution lines 330b may constitute upper redistribution patterns 330.

A width 330W in the first direction D1 of the upper redistribution pattern 330 may range from, for example, about 0.1 nm to about 5 nm. The upper redistribution pattern 330 may be connected to the first semiconductor chip SC1, but may not be connected to the second semiconductor chip SC2. The second semiconductor chip SC2 may be, for example, a dummy semiconductor chip.

A first adhesive layer 410 may be formed on an uppermost surface 300U of the upper redistribution substrate 300, and a first connection part 440 may be formed in the first adhesive layer 410.

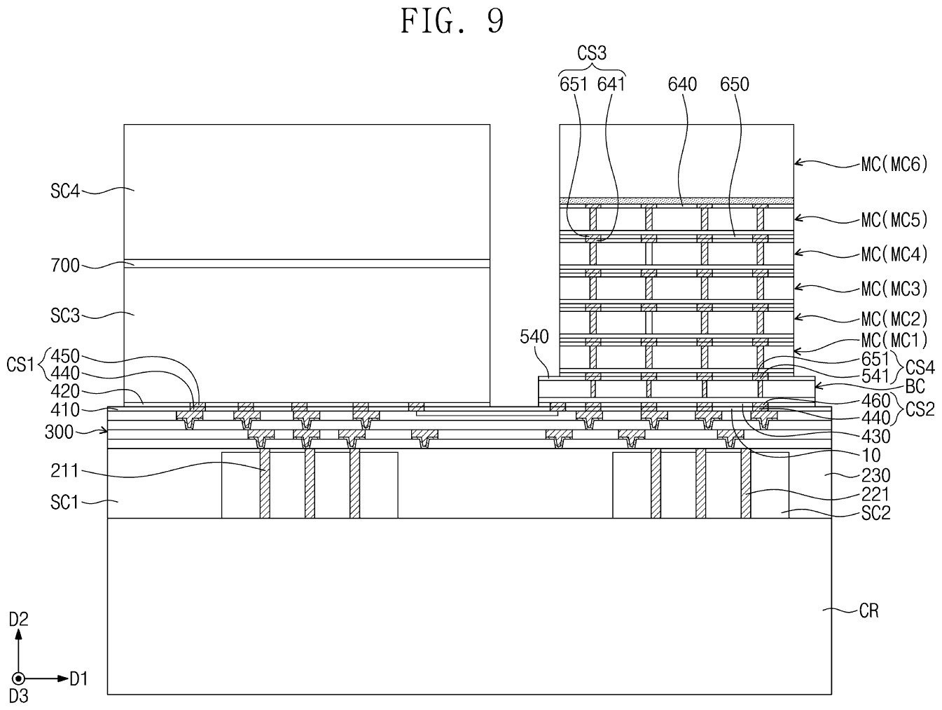

Referring to FIG. 9, a plurality of memory chips MC may be electrically connected to their neighboring memory chips. For example, a thermocompression process may be performed such that an upper adhesive layer 640 of a second memory chip MC2 may be in directly contact with a lower adhesive layer 650 of a third memory chip MC3, and such that an upper connection part 641 in the upper adhesive layer 640 of the second memory chip MC2 may be in direct contact with a lower connection part 651 in the lower adhesive layer 650 of the third memory chip MC3. The thermocompression process may achieve a direct bonding, or a hybrid copper bonding, between the upper connection part 641 and the lower connection part 651, thereby forming a third connection structure CS3. The second memory chip MC2 and the third memory chip MC3 may be connected through the third connection structure CS3. The plurality of memory chips MC may be connected to their neighboring memory chips through substantially the same method as the method discussed above.

A base chip BC may be electrically connected to a lowermost one (e.g., a first memory chip MC1) among the plurality of memory chips MC. For example, a thermocompression process may cause a fourth adhesive layer 540 on the base chip BC to directly contact a lower adhesive layer 650 of the lowermost memory chip (e.g., the first memory chip MC1).

The thermocompression process may cause a lower connection part 651 in the lower adhesive layer 650 of the lowermost memory chip (e.g., the first memory chip MC1) to directly contact a fourth connection part 541 in the fourth adhesive layer 540 of the base chip BC.

The thermocompression process may achieve a direct bonding, or a hybrid copper bonding, between the lower connection part 651 and the fourth connection part 541, thereby forming a fourth connection structure CS4. The lowermost memory chip (e.g., the first memory chip MC1) and the base chip BC may be connected through the fourth connection structure CS4.

The upper redistribution substrate 300 may be mounted thereon with a first stack structure that includes a second adhesive layer 420, a second connection part 450 formed in the second adhesive layer 420, a third semiconductor chip SC3 formed on the second adhesive layer 420, and a fourth semiconductor chip SC4 formed on the third semiconductor chip SC3. The fourth semiconductor chip SC4 may be adhered to the third semiconductor chip SC3 by a die adhesive layer 700.

The upper redistribution substrate 300 may be mounted thereon with a second stack structure that includes a third adhesive layer 430, a third connection part 460 formed in the third adhesive layer 430, the base chip BC formed on the third adhesive layer 430, and the plurality of memory chips MC stacked in the second direction D2 on the base chip BC. The first stack structure and the second stack structure may be spaced apart horizontally (e.g., in the first direction D1) from each other on the upper redistribution substrate 300.

The third semiconductor chip SC3 and the base chip BC may be spaced apart from each other in the first direction D1. The second adhesive layer 420 and the third adhesive layer 430 may be positioned to contact each other, and the second connection part 450 and the third connection part 460 may be positioned to contact each other.

A thermocompression process may cause the first adhesive layer 410 and the second adhesive layer 420 to directly contact each other. The thermocompression process may achieve a direct bonding, or a hybrid copper bonding, between the first connection part 440 and the second connection part 450, thereby forming a first connection structure CS1. The third semiconductor chip SC3 and the upper redistribution substrate 300 may be electrically connected to each other through the first connection structure CS1.

The thermocompression process may cause the first adhesive layer 410 and the third adhesive layer 430 to directly contact each other. The thermocompression process may achieve a direct bonding, or a hybrid copper bonding, between the first connection part 440 and the third connection part 460, thereby forming a second connection structure CS2. The base chip BC and the upper redistribution substrate 300 may be electrically connected to each other through the second connection structure CS2.

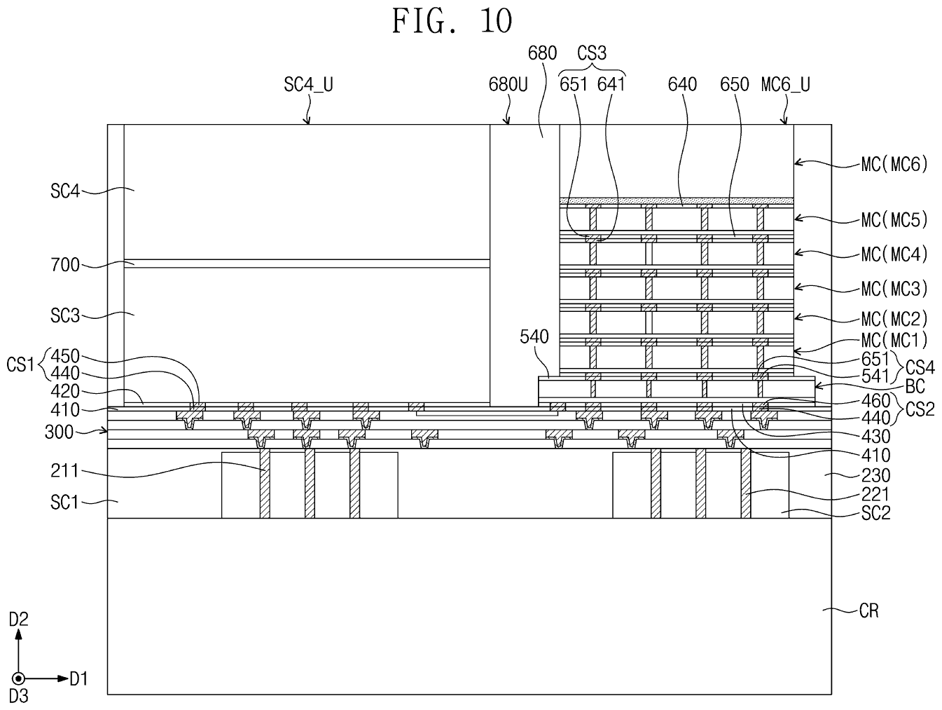

Referring to FIG. 10, an upper dielectric layer 680 may cover the third semiconductor chip SC3, the fourth semiconductor chip SC4, the base chip BC, and the plurality of memory chips MC. The formation of the upper dielectric layer 680 may include, for example, depositing an organic dielectric material on the upper redistribution substrate 300 and planarizing the organic dielectric material until an uppermost surface SC4_U of the fourth semiconductor chip SC4 is exposed. The planarization process may cause the uppermost surface SC4_U of the fourth semiconductor chip SC4 to be positioned on the same plane as a plane of an uppermost surface MC6_U of an uppermost one (e.g., a sixth memory chip MC6) among the plurality of memory chips MC. The planarization process may cause an uppermost surface 680U of the upper dielectric layer 680 to be positioned on the same plane as the plane of the uppermost surface SC4_U of the fourth semiconductor chip SC4 and the plane of the uppermost surface MC6_U of the uppermost memory chip (e.g., the sixth memory chip MC6) among the plurality of memory chips MC.

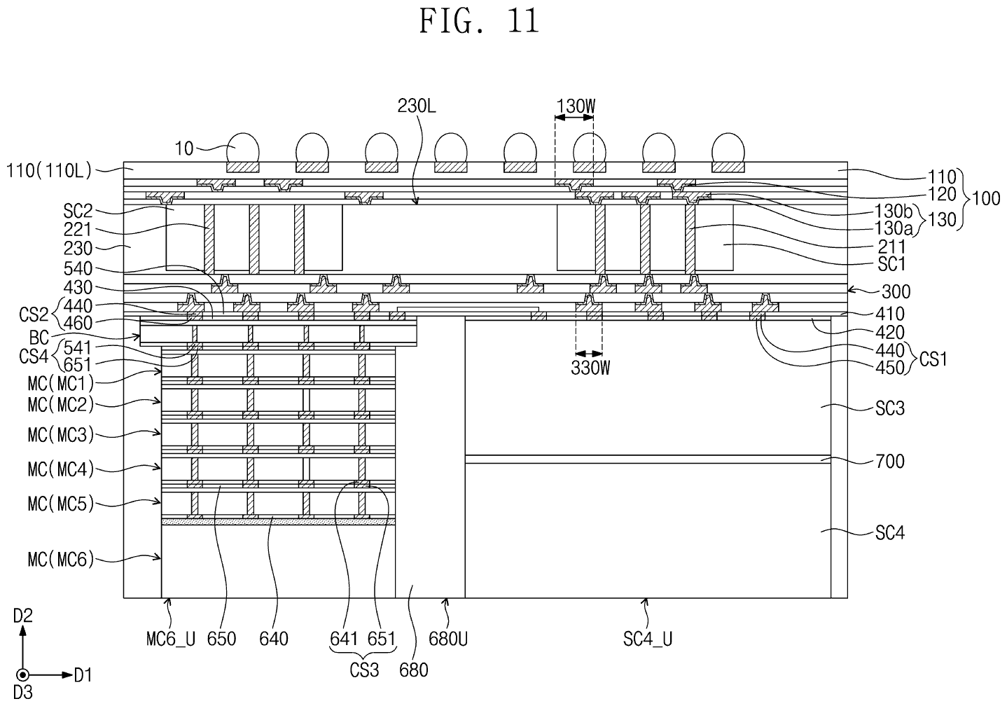

Referring to FIG. 11, a lower substrate 100 may be formed beneath the lower dielectric layer 230. The formation of the lower substrate 100 may include, for example, flipping the carrier substrate CR and a resultant structure on the carrier substrate CR, and then removing the carrier substrate CR to expose a bottom surface 230L of the lower dielectric layer 230, forming lower redistribution dielectric layers 110 on the exposed bottom surface 230L of the lower dielectric layer 230, forming lower redistribution contact holes that penetrate the lower redistribution dielectric layers 110, forming lower redistribution seed patterns 120 that partially fill the lower redistribution contact holes and extend onto top surfaces of the lower redistribution dielectric layers 110, and performing an electroplating process in which the lower redistribution seed patterns 120 are used to form lower redistribution contacts 130a and lower redistribution lines 130b. The lower redistribution contacts 130a may fill unoccupied portions of the lower redistribution contact holes, and the lower redistribution lines 130b may extend onto the lower redistribution dielectric layers 110. The lower redistribution contacts 130a and the lower redistribution lines 130b may constitute lower redistribution patterns 130.

A width 130W in the first direction D1 of the lower redistribution pattern 130 may be greater than a width 330W in the first direction D1 of the upper redistribution pattern 330. A range of from about 1:10 to about 1:5 may be a ratio of the width 330W in the first direction D1 of the upper redistribution pattern 330 to the width 130W in the first direction D1 of the lower redistribution pattern 130. The width 130W in the first direction D1 of the lower redistribution pattern 130 may range from, for example, about 10 nm to about 20 nm.

The width 330W in the first direction D1 of the upper redistribution pattern 330 may be a maximum width in the first direction D1 of the upper redistribution pattern 330. The width 130W in the first direction D1 of the lower redistribution pattern 130 may be a maximum width in the first direction D1 of the lower redistribution pattern 130.

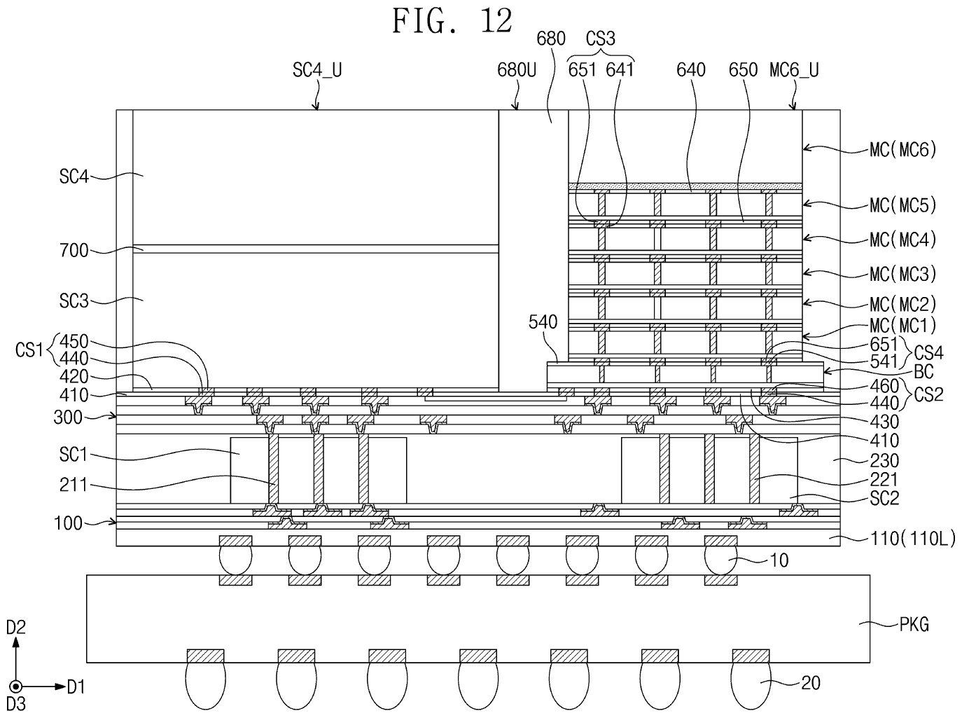

First connection terminals 10 may be formed beneath the lower substrate 100. The first connection terminals 10 may be disposed beneath a lowermost redistribution dielectric layer 110L (see FIG. 12) of the lower redistribution dielectric layers 110.

FIG. 12 illustrates a cross-sectional view taken along the line A-A′ of FIG. 1, showing a semiconductor package according to some embodiments of the present disclosure. For brevity of description, omission may be made to avoid a repetitive explanation of the semiconductor package discussed with reference to FIGS. 1 to 5.

Referring to FIG. 12, a semiconductor package discussed with reference to FIGS. 1 to 5 may be disposed on a package substrate PKG. The package substrate PKG may be, for example, one from among a printed circuit board, a semiconductor chip, and a semiconductor package. For example, a lower substrate 100 may be disposed on the package substrate PKG.

The lower substrate 100 may be provided thereon with a first semiconductor chip SC1, a second semiconductor chip SC2, a third semiconductor chip SC3, a fourth semiconductor chip SC4, a base chip BC, and a plurality of memory chips MC on the base chip BC. The lower substrate 100 may be the lower substrate 100 discussed with reference to FIGS. 1 to 5. The first, second, third, and fourth semiconductor chips SC1, SC2, SC3, and SC4 may be the first, second, third, and fourth semiconductor chips SC1, SC2, SC3, and SC4 discussed with reference to FIGS. 1 to 5. The base chip BC and the plurality of memory chips MC may be the base chip BC and the plurality of memory chips MC discussed with reference to FIGS. 1 to 5.

The lower substrate 100 may be connected (e.g., electrically connected) to the package substrate PKG through first connection terminals 10. Second connection terminals 20 may be disposed on a bottom end portion of the package substrate PKG. The second connection terminals 20 may include, for example, copper bumps, copper pillars, or solder balls.

In a semiconductor package according to some embodiments of the present disclosure, a first semiconductor chip may be a memory chip, and an upper redistribution substrate may be disposed on the first semiconductor chip. Therefore, the first semiconductor chip may have an improved thermal management system and may be prevented from heat-induced degradation of performance. Accordingly, the semiconductor package may be provided with increased reliability.

In addition, a lower dielectric layer and an upper redistribution dielectric layer may include the same material as each other. Thus, as an increased adhesive force is provided between the lower dielectric layer and the upper redistribution dielectric layer, the semiconductor package may have increased reliability.

Moreover, according to some embodiments of the present disclosure, as a third semiconductor chip and a base chip are connected through the upper redistribution substrate, a separate connection chip may not be needed, and the semiconductor package may exhibit improved cost-effectiveness.

A lowermost surface of the third semiconductor chip and a lowermost surface of the base chip may be located at the same level as each other. The third semiconductor chip and the base chip may be connected with a shortest route. Thus, a semiconductor package may be provided with a reduced data transfer path.

Moreover, as each of the upper redistribution dielectric layers may include an inorganic dielectric material, it may be possible to achieve a fine patterning of upper redistribution patterns. Therefore, the upper redistribution pattern may be formed to have a relatively small width in a first direction, and integration of the upper redistribution patterns in the upper redistribution substrate may be easily increased. The increase in integration of the upper redistribution patterns may improve connectivity between the third semiconductor chip and the base chip.

Non-limiting example embodiments have been described above with reference to the accompanying drawings. However, embodiments of the present disclosure are not limited to the example embodiments described above, and it will be understood by one of ordinary skill in the art that variations in form and detail may be made therein without departing from the spirit and scope of the present disclosure.

What is claimed is:

1. A semiconductor package, comprising:
a lower substrate;
a first semiconductor chip on the lower substrate;
a second semiconductor chip on the lower substrate and spaced apart from the first semiconductor chip in a first direction, the first direction being parallel to a top surface of the lower substrate;
a lower dielectric layer on the lower substrate, the first semiconductor chip, and the second semiconductor chip;
an upper redistribution substrate on the lower dielectric layer;
a third semiconductor chip on the upper redistribution substrate;
a base chip on the upper redistribution substrate and spaced apart from the third semiconductor chip in the first direction; and
at least one memory chip stacked in a vertical direction on the base chip, the vertical direction being perpendicular to the top surface of the lower substrate, and
wherein the lower dielectric layer comprises an inorganic dielectric material.

2. The semiconductor package of claim 1, wherein
a thickness of the first semiconductor chip in the vertical direction is the same as a thickness of the second semiconductor chip in the vertical direction.

3. The semiconductor package of claim 1, wherein the upper redistribution substrate comprises:
an upper redistribution pattern; and
at least one upper redistribution dielectric layer that is on the upper redistribution pattern,
wherein the at least one upper redistribution dielectric layer comprises an inorganic dielectric material.

4. The semiconductor package of claim 1, wherein the upper redistribution substrate comprises:
an upper redistribution pattern; and
at least one upper redistribution dielectric layer that is on the upper redistribution pattern,
wherein the at least one upper redistribution dielectric layer comprises one or more from among silicon oxide, silicon nitride, and silicon oxynitride.

5. The semiconductor package of claim 1, wherein the lower substrate comprises:
a lower redistribution pattern; and
at least one lower redistribution dielectric layer that is on the lower redistribution pattern,
wherein the at least one lower redistribution dielectric layer comprises a material different from a material of the lower dielectric layer.

6. The semiconductor package of claim 1, wherein the upper redistribution substrate comprises:
an upper redistribution pattern; and
at least one upper redistribution dielectric layer that is on the upper redistribution pattern,
wherein the lower substrate comprises:
a lower redistribution pattern; and
at least one lower redistribution dielectric layer that is on the lower redistribution pattern, and
wherein a width of the upper redistribution pattern in the first direction is less than a width of the lower redistribution pattern in the first direction.

7. The semiconductor package of claim 6, wherein a ratio of the width of the upper redistribution pattern in the first direction to the width of the lower redistribution pattern in the first direction is in a range of 1:10 to 1:5.

8. The semiconductor package of claim 6, wherein the width of the upper redistribution pattern in the first direction is in a range of 0.1 nm to 5 nm, and wherein the width of the lower redistribution pattern in the first direction is in a range of 10 nm to 20 nm.

9. The semiconductor package of claim 1, wherein the first semiconductor chip comprises a first via that penetrates the first semiconductor chip,
wherein the second semiconductor chip comprises a second via that penetrates the second semiconductor chip,
wherein an uppermost surface of the first via and an uppermost surface of the second via are at a same level from the top surface of the lower substrate, and
wherein the first via is electrically connected to the upper redistribution substrate.

10. The semiconductor package of claim 1, further comprising a fourth semiconductor chip on the third semiconductor chip,
wherein an uppermost surface of the fourth semiconductor chip is at a same level as a level of an uppermost surface of an uppermost one of the at least one memory chip.

11. A semiconductor package, comprising:
a first semiconductor chip;
a second semiconductor chip spaced apart from the first semiconductor chip in a first direction;
a lower dielectric layer on the first semiconductor chip and the second semiconductor chip;
an upper redistribution substrate on the lower dielectric layer;
a third semiconductor chip on the upper redistribution substrate;
a base chip on the upper redistribution substrate and spaced apart from the third semiconductor chip in the first direction;
at least one memory chip stacked in a second direction on the base chip, the second direction being perpendicular to the first direction; and
an upper dielectric layer on the upper redistribution substrate, and on a side surface of the third semiconductor chip, the base chip, and the at least one memory chip,
wherein the upper dielectric layer comprises a material different from a material of the lower dielectric layer.

12. The semiconductor package of claim 11, further comprising a lower substrate beneath the first semiconductor chip and the second semiconductor chip,
wherein the upper redistribution substrate comprises:
at least one upper redistribution pattern; and
at least one upper redistribution dielectric layer that is on the at least one upper redistribution pattern,
wherein the lower substrate comprises:
at least one lower redistribution pattern; and
at least one lower redistribution dielectric layer that is on the at least one lower redistribution pattern, and
wherein the at least one upper redistribution dielectric layer comprises a material different from a material of the at least one lower redistribution dielectric layer.

13. The semiconductor package of claim 12, wherein a number of the at least one upper redistribution pattern is greater than a number of the at least one lower redistribution pattern.

14. The semiconductor package of claim 11, wherein the lower dielectric layer comprises an inorganic dielectric material.

15. The semiconductor package of claim 11, wherein a lowermost surface of the third semiconductor chip is at a same level as a level of a lowermost surface of the base chip.

16. The semiconductor package of claim 11, further comprising:
a first adhesive layer on an uppermost surface of the upper redistribution substrate; and
a second adhesive layer beneath a lowermost surface of the third semiconductor chip,
wherein the first adhesive layer is between the second adhesive layer and the upper redistribution substrate,
wherein the second adhesive layer is between the first adhesive layer and the third semiconductor chip, and
wherein the first adhesive layer and the second adhesive layer comprise a same material as each other.

17. The semiconductor package of claim 16, further comprising a third adhesive layer beneath a lowermost surface of the base chip,
wherein the third adhesive layer is between the first adhesive layer and the base chip, and
wherein the first adhesive layer and the third adhesive layer comprise a same material as each other.

18. A semiconductor package, comprising:
a package substrate;
a lower substrate on the package substrate;
a first semiconductor chip on the lower substrate;
a second semiconductor chip spaced from the first semiconductor chip apart in a first direction, the first direction being parallel to a top surface of the package substrate;
an upper redistribution substrate on the first semiconductor chip and the second semiconductor chip;
a third semiconductor chip on the upper redistribution substrate;
a base chip on the upper redistribution substrate and spaced apart from the third semiconductor chip in the first direction; and
at least one memory chip stacked in a second direction on the base chip, the second direction being perpendicular to the top surface of the package substrate,
wherein an uppermost surface of the first semiconductor chip is at a same level as a level of an uppermost surface of the second semiconductor chip, and
wherein a lowermost surface of the third semiconductor chip is at a same level as a level of a lowermost surface of the base chip.

19. The semiconductor package of claim 18, wherein the lower substrate comprises:
a lower redistribution pattern; and
at least one lower redistribution dielectric layer that is on the lower redistribution pattern,
wherein the upper redistribution substrate comprises:
an upper redistribution pattern; and
at least one upper redistribution dielectric layer that is on the upper redistribution pattern, and
wherein the at least one lower redistribution dielectric layer comprises a material different from a material of the at least one upper redistribution dielectric layer.

20. The semiconductor package of claim 18, wherein the upper redistribution substrate comprises:
an upper redistribution pattern; and
at least one upper redistribution dielectric layer that is on the upper redistribution pattern,
wherein the lower substrate comprises:
a lower redistribution pattern; and
at least one lower redistribution dielectric layer that is on the lower redistribution pattern, and
wherein a width of the upper redistribution pattern in the first direction is less than a width of the lower redistribution pattern in the first direction.
